(19) United States
(12) Patent Application Publication
(10) Pub. No.: US 2006/0009026 A1
(43) Pub. Date: Jan. 12, 2006

(54) Method of fabricating wiring board

(75) Inventors: Kumiko Sawaguchi, Hitachi (JP); Toshinori Koyama, Nagano (JP); Syuichi Tanaka, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO., LTD., Nagano-shi (JP)

(21) Appl. No.: 11/167,583

(22) Filed: Jun. 28, 2005

(30) Foreign Application Priority Data
Jul. 7, 2004 (JP) 2004-200051
Jan. 17, 2005 (JP) 2005-8623

(51) Int. Cl. H01L 21/4763

(52) U.S. Cl. 438/622; 438/637

(57) ABSTRACT

In a wiring board fabrication method including a wiring formation process using a damascene method, via holes reaching an underlying wiring layer are formed in an interlayer insulating layer formed on the underlying wiring layer, smears caused at that time are removed, and then a photosensitive permanent resist layer is formed on the interlayer insulating layer so as to have opening portions (wiring grooves) according to the shape of a required wiring pattern located above the via holes. Next, a seed layer is formed on the entire surface, a conductor layer is formed on the seed layer by filling the insides of the via holes and the opening portions (wiring grooves), and then the surface of the conductor layer is polished and planarized until the photosensitive permanent resist layer is exposed, thus forming the required wiring pattern.

### CROSS-REFERENCE TO RELATED APPLICATIONS

This application is based on and claims priority of Japanese Patent Applications No. 2004-200051 filed on Jul. 7, 2004, and No. 2005-8623 filed on Jan. 17, 2005, the entire contents of which are incorporated herein by reference.

### BACKGROUND OF THE INVENTION

(a) Field of the Invention

The present invention relates to a wiring board fabrication method. More specifically, the present invention relates to a wiring board fabrication method including a wiring formation process using a damascene method adapted for the formation of fine wirings.

(b) Description of the Related Art

In recent years, the increasing integration degrees and speeds of LSIs have encouraged the trend toward a larger number of wiring layers and finer wirings. In particular, in logic devices, the reduction in the minimum pitch of wiring in accordance with the gate length is essential for the realization of enhanced transistor characteristics. Additionally, wiring structures are required which withstand the use under conditions of high current densities. When a wiring pitch is reduced, signal delays caused by capacitances between interconnections and wiring resistance, which have been not so serious problems heretofore, become non-negligible. In order to avoid this, it is necessary to use a wiring material having a low resistance and an interlayer dielectric having a low dielectric constant. Heretofore, aluminum (Al) has been used as a wiring material. Recently, copper (Cu) is used which can realize an underlying wiring resistance compared to Al when the interconnections formed by them have an equal interconnection cross sections. Since the thickness of interconnection formed by Cu can be more reduced compared to that formed by Al when the interconnections have an equal wiring pitch and an equal wiring resistance, capacitances between interconnections can be consequently reduced. However, in the case where multilayer wiring is formed using Cu, the etching of Cu and the burying of an interlayer dielectric are necessary. There is a disadvantage in that such processing cannot be easily performed in the state of the art.

In view of this, as technologies for forming wiring, “damascene” which does not require the etching of Cu has been brought into mainstream, in place of a dry etching technique heretofore used in Al wiring technology. Damascene technologies include single damascene and dual damascene. Single damascene is a technology described as follows: grooves which become interconnections are formed in an interlayer dielectric by etching, a barrier metal layer as a diffusion prevention layer is further deposited, a Cu film is deposited thereon, then the Cu and the barrier metal layer in upper portions of the wiring grooves are removed by chemical mechanical polishing (CMP) and the like, and planarization is performed, thus forming the interconnections. On the other hand, dual damascene is a technology described as follows: via holes for electrical contact with an underlying wiring layer are formed simultaneously with wiring grooves, and interconnections and via plugs are simultaneously formed by performing the deposition of a barrier metal layer, the deposition of a Cu film, and CMP, respectively, one time. Further, multilayer wiring can be formed by repeating these steps until a required number of layers are obtained.

As described above, in a damascene method, whether it is single damascene or dual damascene, after a wiring material (Cu) is finished being filled into wiring grooves and via holes, a process for performing planarization by machining such as CMP is required. When doing the process, noise occurs due to mechanical vibration because a machine which performs polishing has a rotating structure, and there occurs a problem in that polishing end cannot be easily detected because of this noise. Further, since the polishing end cannot be easily detected, it is difficult to stop polishing within an appropriate range. For example, in the case of over-polishing, there occurs a problem in that interconnections become narrow (i.e., the cross sections of the interconnections become small), and that the wiring resistance becomes high (i.e., the conductivity is lowered). Meanwhile, in the case of under-polishing, there occurs a problem in that a leak current is caused by a remaining part of the barrier metal layer, and, in some cases, a short circuit is caused. Furthermore, since Cu and the barrier metal are simultaneously polished, recessed portions called “dishing” appear on the interconnections (Cu) due to the difference in hardness between Cu and the barrier metal (generally, Cu is softer).

The applicant of this application has previously proposed a technology for solving the above-described problems (e.g., Japanese unexamined Patent Publication (JPP) 2000-332111). In this technology (see FIGS. 1A to 1E of JPP 2000-332111), disclosed is a process for forming wiring grooves 12 patterned in required shapes and via holes 13 reaching an underlying wiring layer 10 in an interlayer dielectric 11 formed on the underlying wiring layer 10. However, this technology has not clarified at which stage processing (desmear) for removing resin pieces (smears) generally caused when the via holes are formed should be performed. Further, in the case where the patterning of the wiring grooves and the formation of the via holes are performed at different stages, the order of individual processings has also been not particularly clarified.

### SUMMARY OF THE INVENTION

An object of the present invention is to provide a wiring board fabrication method by which fine wiring can be realized through an approach different from that of the above-described technology (JPP 2000-332111).

To attain the above object, according to one aspect of the present invention, there is provided a method of fabricating a wiring board, including a wiring formation process using a damascene method, the wiring formation process including the steps of: forming via holes reaching an underlying wiring layer, in an interlayer insulating layer formed on the underlying wiring layer; removing smears caused when the via holes have been formed; forming on the interlayer insulating layer a photosensitive permanent resist layer having opening portions according to a shape of a required wiring pattern located above the via holes; and forming the required wiring pattern by filling conductive material into the via holes and the opening portions.

According to the wiring board fabrication method of this aspect, the opening portions of the photosensitive permanent resist layer patterned in a required shape on the interlayer insulating layer are utilized for forming a target wiring pattern. Generally, such a photosensitive resist layer can be considerably finely and accurately patterned at an exposed surface. Accordingly, even if the film thickness of the resist layer is reduced (i.e., the depth of the opening portion defining a wiring pattern is reduced), it is possible to cope with the formation of sufficiently fine and accurate wiring. Namely, this method can contribute to a realization of fine wiring.

Also, according to another aspect of the present invention, there is provided a method of fabricating a wiring board, including a wiring formation process using a damascene method, the wiring formation process including the steps of: forming via holes reaching an underlying wiring layer, in an interlayer insulating layer formed on the underlying wiring layer; forming on the interlayer insulating layer a photosensitive permanent resist layer having opening portions according to a shape of a required wiring pattern located above the via holes; removing smears caused when the via holes have been formed; and forming the required wiring pattern by filling conductive material into the via holes and the opening portions.

Also, according to still another aspect of the present invention, there is provided a method of fabricating a wiring board, including a wiring formation process using a damascene method, the wiring formation process including the steps of: forming, on an interlayer insulating layer formed on an underlying wiring layer, a photosensitive permanent resist layer having opening portions according to a shape of a required wiring pattern located above the underlying wiring layer; forming via holes reaching the underlying wiring layer in the interlayer insulating layer; removing smears caused when the via holes have been formed; and forming the required wiring pattern by filling conductive material into the via holes and the opening portions.

### BRIEF DESCRIPTION OF THE DRAWINGS

FIGS. 1A to 1G are cross-sectional views showing a wiring formation process in a wiring board fabrication method according to one embodiment of the present invention;

FIGS. 2A to 2C are views (by photography) showing the states of the surfaces of photosensitive permanent resist layers for the cases where roughening by dry etching has been performed and not performed;

FIG. 3 is a view for explaining the effect of polishing performed in the step of FIG. 1G;

FIG. 4 is a cross-sectional view partially showing one constitution example of a wiring board fabricated according to the embodiment of FIGS. 1A to 1G;

FIGS. 5A to 5G are cross-sectional views showing a wiring formation process according to one modification of the embodiment of FIGS. 1A to 1G; and

FIGS. 6A to 6G are cross-sectional views showing a wiring formation process according to another modification of the embodiment of FIGS. 1A to 1G.

### DESCRIPTION OF THE PREFERRED EMBODIMENTS

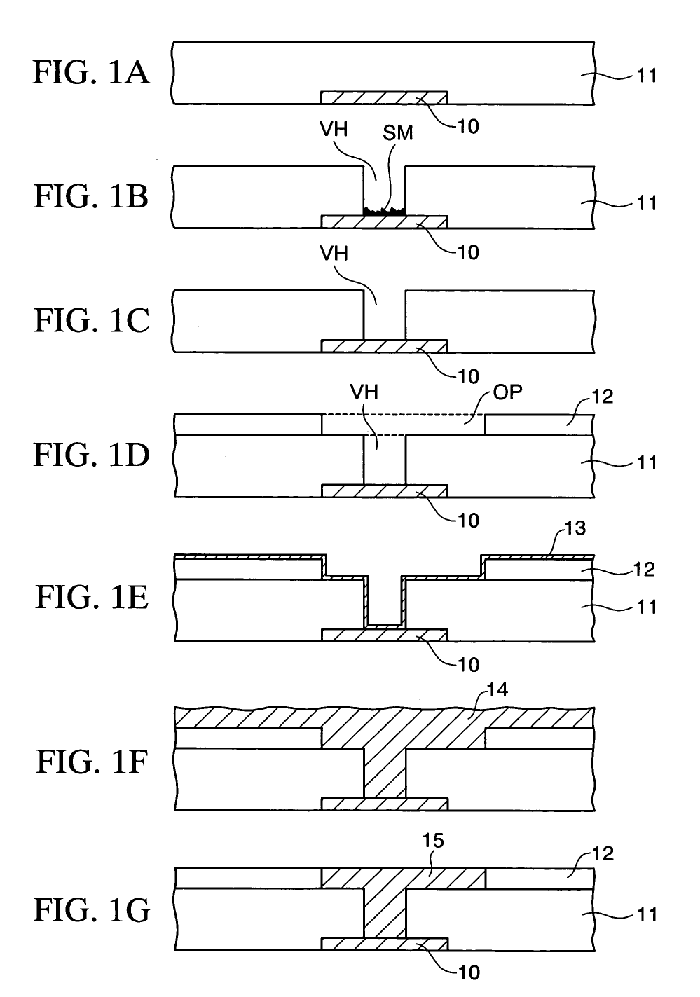

Hereinafter, a wiring board fabrication method according to one embodiment of the present invention will be described with reference to FIGS. 1A to 1G showing a wiring formation process thereof. In this embodiment, the wiring formation is performed using a dual damascene method as described below.

First, in the first step (FIG. 1A), an interlayer insulating layer 11 is formed on the entire surface so as to cover an underlying wiring layer 10 (wiring layer in which copper (Cu) is used as wiring material). As the material of the interlayer insulating layer 11, for example, thermosetting resin such as epoxy resin, phenolic resin, acrylic resin, or the like, is used. Alternatively, photosensitive resin, such as epoxy resin or polyimide resin, which has the property of hardening by irradiation with light such as ultraviolet light, may be used.

In the next step (FIG. 1B), via holes VH which reaches the underlying wiring layer 10 are formed in the interlayer insulating layer 11 formed on the underlying wiring layer 10, for example, using a laser such as a CO₂ laser or a YAG laser. At this time, resin pieces (resin smears) SM caused by the hole making using the laser remain on the underlying wiring layer 10 (Cu) in the via holes VH. Incidentally, although the via holes VH are formed using the laser in this step, the via holes VH can be formed by ordinary photolithography in the case where the interlayer insulating layer 11 formed in the preceding step is made of photosensitive resin.

In the next step (FIG. 1C), the resin smears SM remaining on the underlying wiring layer 10 (Cu) in the preceding step are removed by wet etching using a desmear solution. Specifically, using an alkaline permanganate solution (solution containing sodium permanganate or potassium permanganate) as the desmear solution, the relevant resin (smears SM) swelled in advance is dissolved and removed by this solution. Thus, the surface of the underlying wiring layer 10 (Cu) is cleaned. This makes it possible to obtain improved adhesiveness to a plated film when plating is performed in a later step. Incidentally, desmear is performed by wet etching in this step. However, for example, dry etching using plasma may be used instead.

In the next step (FIG. 1D), a photosensitive permanent resist layer 12 patterned in a required shape is formed on the interlayer insulating layer 11. For example, insulating resin such as epoxy resin or polyimide resin is used as the material of the photosensitive permanent resist layer 12. As for characteristics thereof, the linear expansion coefficient is 70 ppm/° C. or less, and the tensile strength is 70 MPa or more. Further, as for the form thereof, liquid or film-shaped one (e.g., dry film) is used. Specifically, photosensitive resist is applied (in the case of liquid) or laminated (in the case of a film-shaped one) on the entire surface including the insides of the via holes VH, and exposed to light and developed (patterning of resist) using a mask (not shown) patterned in accordance with the shape of a required wiring pattern located above the via holes VH, thereby forming the photosensitive permanent resist layer 12 having opening portions OP (indicated by dashed lines) according to the shape of the wiring pattern. These opening portions OP formed in the photosensitive permanent resist layer 12 define “wiring grooves” in which the wiring pattern is to be formed.

In the next step (FIG. 1E), a seed layer 13 of copper (Cu) is formed on the entire surface (on the underlying wiring layer 10, the interlayer insulating layer 11, and the photosensitive permanent resist layer 12) including the inner walls of the via holes VH and the opening portions (wiring grooves) OP, for example, by electroless plating. At this time, since the surface of the underlying wiring layer 10 has been cleaned by the desmearing, the reliability of the electrical connection between the seed layer 13 and the underlying wiring layer 10 can be ensured. Incidentally, electroless plating is performed in this step. However, for example, sputtering, vapor deposition, or the like, may be performed instead.

In the next step (FIG. 1F), using the seed layer 13 as a power-supplying layer, a conductor layer 14 of Cu is formed on the seed layer 13 by electrolytic Cu plating so as to fill the insides of the via holes VH and the opening portions (wiring grooves) OP. In this embodiment, the electrolytic Cu plating is performed by combining pulse plating and DC plating. Specifically, pulse plating is performed until the via holes VH are filled, and then the wiring portions (opening portions OP) are filled by DC plating. Conditions for the pulse plating are as follows: the current density in the forward direction (direction with which Cu is deposited) is 0.5 to 10 A/dm², and the plating time therefor is 0.1 msec to 1 sec; the current density in the reverse direction (direction with which Cu is dissolved) is 0.1 to 10 A/dm², and the plating time therefor is 0.1 msec to 100 msec. Further, the DC plating is performed under the condition that the current density is 0.5 to 5 A/dm².

Incidentally, at the time when this step has been finished, since Cu deposition by electrolytic plating has been merely performed, the surface of the conductor layer 14 (Cu) is not even as illustrated. Further, the conductor layer 14 is formed by electrolytic plating in this step. However, for example, electroless plating, CVD, or the like, can also be used instead.

In the final step (FIG. 1G), the surface of the conductor layer 14 (Cu) is planarized, and this planarization is continued until the surface of the photosensitive permanent resist layer 12 is exposed. Specifically, the surface of the conductor layer 14 is polished and planarized by mechanical polishing such as buffing or belt sanding, and the polishing is stopped at the time when the surface of the photosensitive permanent resist layer 12 has been exposed. Buffing is a method in which a roll buff (non-woven fabric) having an abrasive buried therein is rotated and pressed against an object surface (in this case, the surface of the conductor layer 14) to polish the object surface while the object surface and the buff are being moistened with cooling water. On the other hand, belt sanding is a method in which a sanding belt (having an abrasive buried therein) is carried on a roller rotating and is pressed against an object surface to polish the object surface while the object surface and the sanding belt are being similarly moistened with cooling water. For example, in the case of buffing, a polishing object which is being horizontally carried on a line having a length of 1 m at a speed of 1 m/min. is polished (i.e., one cycle time is 60 sec) using two types of buff rolls having grit sizes of 300 and 600, and this processing is repeated approximately four to six times.

Alternatively, a method may be used in which buffing and chemical polishing using an etchant are combined. Specifically, the above-described buffing (one cycle time is 60 sec) is repeated twice, and then a polishing object is chemically polished for approximately 120 sec by spray etching using a sulfuric acid-hydrogen peroxide etchant (having an etching rate of 1 μm/min. to 5 μm/min., preferably 2 μm/min.).

Further, possible methods of planarizing the surface of the conductor layer 14 includes a method using chemical mechanical polishing (CMP) other than the above-described mechanical polishing (buffing) and the like. However, as described later, considering the time required for polishing, the above-described mechanical polishing (buffing) and the like are more suitable.

By the above-described steps, a wiring layer (wiring pattern) 15 is formed to fill the opening portions (wiring grooves) OP of the photosensitive permanent resist layer 12 patterned in a required shape and the via holes VH under the opening portions OP.

Furthermore, although not shown in FIGS. 1A to 1G, a multilayer wiring board can be fabricated by repeating the above-described wiring formation process as needed until a required number of wiring layers are obtained, forming a protective film (e.g., solder resist layer) on each of both surfaces of the resultant structure so that pad portions delimited in required portions of the outermost wiring patterns are exposed, appropriately performing surface treatment on the pad portions exposed from the protective films, and then, when necessary, forming external connection terminals (e.g., solder bumps) on the pad portions exposed from the protective films.

As described above, in the wiring formation method according to this embodiment, the opening portions (wiring grooves) OP of the photosensitive permanent resist layer 12 patterned in a required shape on the interlayer insulating layer 11 are utilized for forming the target wiring pattern 15. Generally, such a photosensitive resist layer can be considerably finely and accurately patterned at an exposed surface. Accordingly, even if the film thickness of the photosensitive permanent resist layer 12 is reduced (i.e., the depth of the wiring groove OP is reduced), it is possible to cope with the formation of sufficiently fine and accurate wiring. Namely, the fining of the wiring pattern 15 can be realized.

Further, since the photosensitive permanent resist layer 12 is formed after desmear by wet etching has been performed, a material which is not resistant to desmear can also be used. Namely, since desmear is a process of dissolving resin, resin other than smear portions is also dissolved if no measure is taken. Accordingly, in the case where the photosensitive permanent resist layer is formed before desmear is performed, “desmear resistance” is required for the material constituting the resist layer. In this case, a specific material which meets the requirement must be selected. However, in this embodiment, there is no need to do so.

Further, since an insulating resin having predetermined characteristics (a linear expansion coefficient of 70 ppm/° C. or less, and a tensile strength of 70 MPa or more) is used as the material of the photosensitive permanent resist layer 12, reliability as an insulating film (resist layer 12) can be ensured. In connection with this, the present inventors carried out reliability tests of pressure cooker test (PCT) and thermal shock (T/S) under the following conditions: for PCT, 100° C., 100% RH (2.1 atm.); for T/S, the state of 125° C. for five minutes and the state of −55° C. for five minutes, which constitute one cycle, are alternately repeated. Namely, when PCT was performed for 96 hours on an insulating film made of a material (e.g., a material having a linear expansion coefficient of 80 ppm/° C. and a tensile strength of 60 MPa) which does not meet the above-described characteristics, interlayer delamination occurred between the relevant insulating film and a conductor layer (corresponding to the conductor layer 14 of FIG. 1F) formed thereon. When 1000 T/S cycles were further carried out, a crack appeared. On the other hand, as for an insulating film made of a material (e.g., a material having a linear expansion coefficient of 70 ppm/° C. and a tensile strength of 70 MPa) which meets the above-described characteristics, no anomaly was observed in the relevant insulating film, even after PCT was carried out for 168 hours and further 1000 T/S cycles were carried out (reliability is ensured).

Moreover, when necessary (e.g., in the case where the seed layer 13 is partially stripped off when the seed layer 13 is formed by electroless plating because adhesive strength to the interlayer insulating layer 11 under the seed layer 13 is weak), the surface of the interlayer insulating layer 11 may be roughened, for example, by dry etching after desmearing has been performed (before the photosensitive permanent resist layer 12 is formed), followed by the hardening of photoresist (photosensitive permanent resist layer 12). Alternatively, the surfaces of the interlayer insulating layer 11 and the photosensitive permanent resist layer 12 may be similarly roughened by dry etching or the like after the photosensitive permanent resist layer 12 has been formed (before the seed layer 13 is formed). Such roughening can improve the adhesiveness between the seed layer 13 and the interlayer insulating layer 11, or between the seed layer 13 and each of the interlayer insulating layer 11 and the photosensitive permanent resist layer 12.

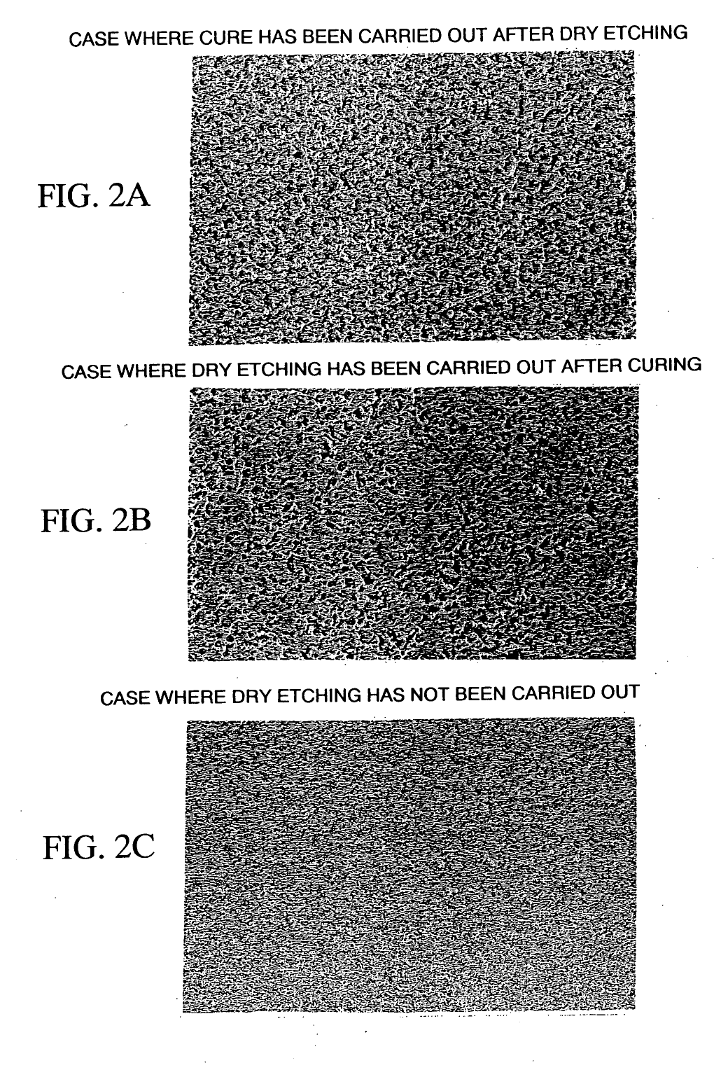

FIGS. 2A to 2C are views (by photography) for additionally explaining the effect thereof, and show the states of the surface of the photosensitive permanent resist layer 12 for the case where roughening by dry etching has been performed, in comparison with that for the case where dry etching has not been performed. FIG. 2A shows the case where the photosensitive permanent resist layer 12 has been cured after roughening by dry etching. FIG. 2B shows the case where dry etching (roughening) has been performed after the curing of the photosensitive permanent resist layer 12. FIG. 2C shows the case where dry etching (roughening) has not been performed. When electroless Cu plating was performed (formation of the seed layer 13 of FIG. 1E) in the cases of FIGS. 2A to 2C, the delamination of the seed layer 13 was not observed in the case of FIG. 2A; while, in each of the cases of FIGS. 2B and 2C, partial delamination of the seed layer 13 was observed (note that, in the case of FIG. 2B, the degree of delamination was smaller compared to that of the case of FIG. 2C).

Further, when the conductor layer 14 is formed by electrolytic Cu plating in the step of FIG. 1F, the via holes VH which are deep in the thickness direction are selectively filled by pulse plating, and then DC plating is performed. Accordingly, the plating thickness can be reduced in portions (on the photosensitive permanent resist layer 12) where the wiring layer (wiring pattern) 15 is not formed. This greatly contributes to a uniformity in the polishing to be performed in the next step and an improvement in the productivity.

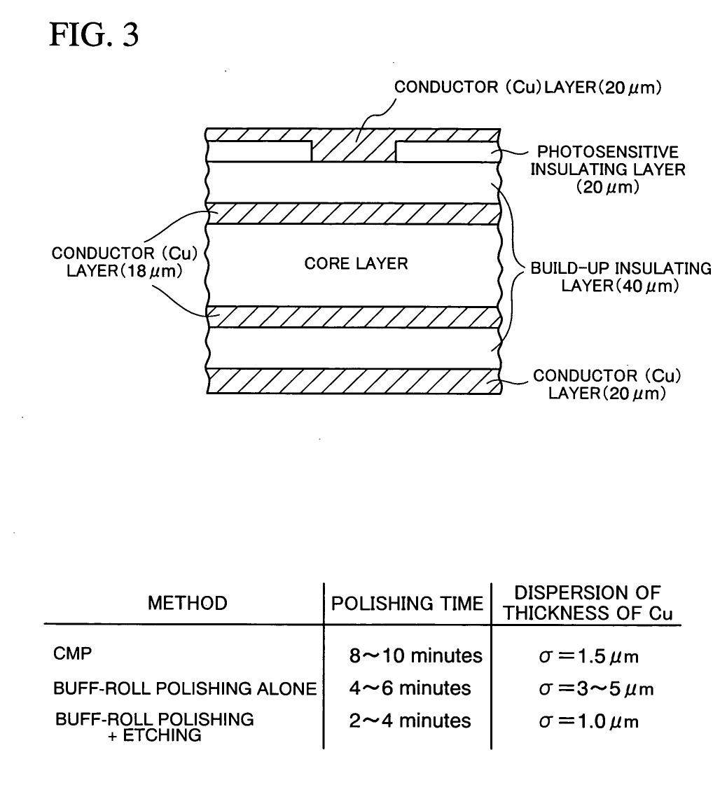

Moreover, in the step of FIG. 1G, the surface of the conductor layer 14 (Cu) is planarized by mechanical polishing (buffing or the like) or the combination of mechanical polishing and chemical polishing by etching. Accordingly, this method has the more advantage in the time required for polishing compared to a method using chemical mechanical polishing (CMP). In connection with this, the inventors prepared wiring board structures (samples) such as shown in FIG. 3, and performed polishing by three types of methods (CMP, buff-roll polishing alone, and buff-roll polishing+etching). As a result, it proved that the polishing time can be more reduced in “buff-roll polishing alone” and “buff-roll polishing+etching” compared to that in “CMP” as illustrated. This reduction in the polishing time greatly contributes to an improvement in the productivity. Further, in the method in which etching is used in combination with buff-roll polishing, the uniformity of the ultimately planarized surface was improved (dispersion of thickness of Cu: s=1.0 μm) by specifying an etchant and an etching rate.

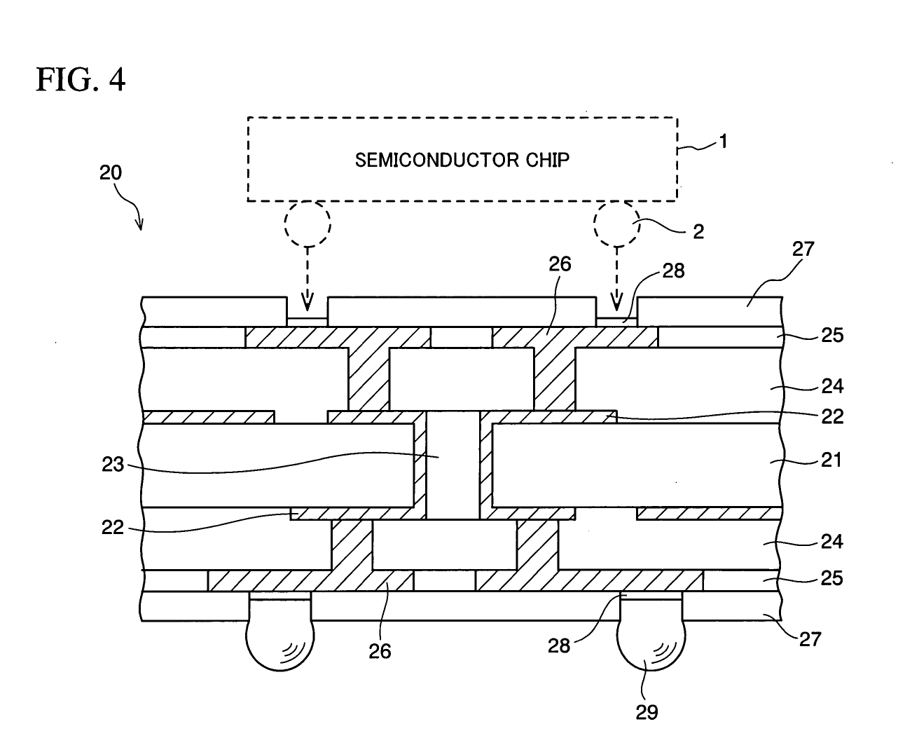

FIG. 4 partially shows one constitution example of a wiring board fabricated using the wiring formation method according to the above-described embodiment.

In the illustrated example, there is shown a constitution example for the case where the aforementioned wiring formation method is applied to a build-up multilayer wiring board used as a semiconductor package of a plastic type and is realized in the form of a ball grid array (BGA) package to which solder bumps (solder balls) as external connection terminals are bonded. As indicated by dashed lines in the drawing, a semiconductor chip 1 is mounted on a wiring board 20 shown in the drawing. The wiring board 20 having the semiconductor chip 1 mounted thereon is mounted on a printed wiring board such as a mother board so as to constitute a semiconductor device.

In this wiring board 20, reference numeral 21 denotes a core substrate which is made of an insulating material (e.g., glass epoxy resin or glass BT resin) and which serves as a base of the wiring board 20, and reference numeral 22 denotes a Cu wiring layer (corresponding to the underlying wiring layer 10 in FIGS. 1A to 1G) which is patterned in required shapes on both surfaces of the core substrate 21. This wiring layer 22 constitutes a first layer (core layer) of the build-up multilayer wiring board in conjunction with the core substrate 21. Further, reference numeral 23 denotes an insulator made of epoxy resin or the like and filled in through holes provided in the core substrate 21; reference numeral 24 denotes an interlayer insulating layer (corresponding to the interlayer insulating layer 11 in FIGS. 1A to 1G) made of epoxy resin or the like and formed on the core substrate 21 and the wiring layer 22; reference numeral 25 denotes a photoresist layer as an insulating layer (corresponding to the photosensitive permanent resist layer 12 in FIGS. 1D to 1G); and reference numeral 26 denotes a Cu wiring layer (corresponding to the wiring pattern 15 in FIG. 1G). This wiring layer 26 is formed so as to fill via holes formed in required portions (corresponding portions on the wiring layers 22) of the interlayer insulating layers 24 and opening portions (wiring grooves) delimited in required portions (corresponding portions above the via holes) of the photoresist layer 25. The insulating layers 24 and 25 and the wiring layer 26 constitute the second layer of the build-up multilayer wiring board.

Moreover, reference numeral 27 denotes a solder resist layer as a protective film. The solder resist layer 27 is formed on the photoresist layer 25 and the wiring layer (wiring pattern) 26 to cover the entire surface in such a manner that pad portions delimited in required portions of the wiring pattern are exposed. Further, a nickel (Ni)/gold (Au) plated layer 28 is deposited on each of the pad portions of the wiring patterns 26 which are exposed from the solder resist layers 27. Furthermore, an external connection terminal 29 (e.g., solder bump) is bonded to the Ni/Au plated layer 28 on one surface (lower surface in the illustrated example).

When the semiconductor chip 1 is mounted on the wiring board 20, the semiconductor chip 1 is flip-chip bonded to the wiring board 20 so that electrode terminals 2 (e.g., solder bumps or gold (Au) stud bumps) bonded to pads of the semiconductor chip 1 are electrically connected to the pad portions of the wiring pattern 26 which are exposed from the solder resist layer 27 on the upper side, and further underfill resin (e.g., epoxy resin) is filled into the space between the semiconductor chip 1 and the relevant solder resist layer and cured, thus bonding the semiconductor chip 1 to the wiring board 20. Further, when the wiring board 20 is mounted on a printed wiring board such as a mother board, solder balls (solder bumps 29) which serve as external connection terminals are similarly bonded by reflow to the pad portions of the wiring pattern 26 which are exposed from the solder resist layer 27 on the lower side, the relevant pad portions are connected to corresponding pads or lands on the printed wiring board using the solder bumps 29, and underfill resin is filled, thus bonding the wiring board 20 to the printed wiring board.

In the constitution example shown in FIG. 4, the external connection terminals (solder bumps 29) are provided, but they do not necessarily need to be provided. It is essential only that the pad portions (Ni/Au plated layer 28) of the outermost wiring layer 26 are exposed from the solder resist layer 27 so that external connection terminals can be bonded thereto when necessary. Further, in the illustrated example, there are formed four wiring layers 22 and 26 in total, two layers on each side of the core substrate 21. However, it is a matter of course that the number of wiring layers may be further increased as needed.

Moreover, in the constitution example of FIG. 4, the description has been given by taking as an example the case where the wiring formation method according to the embodiment of FIGS. 1A to 1G is realized in the form of a BGA package. However, the wiring formation method can also be similarly applied to the case where it is realized in the form of a pin grid array (PGA) package in which a large number of pins as external connection terminals are stood on one surface of a substrate. In this case, the bonding of the pins is performed, for example, by mounting an appropriate amount of solder on the pad portions of the wiring pattern 26 which are exposed from the solder resist layer 27 on the lower side; placing, on the solder, head portions of the T-shaped pins which have the head portions having large diameters; and performing reflow to cure the solder.

In the wiring formation method (FIGS. 1A to 1G) according to the aforementioned embodiment, the description has been given by taking as an example the case where the process is carried out by performing, in order, the formation of the via holes VH in the interlayer insulating layer 11, the removal of the resin smears SM (desmearing), and the patterning of the wiring grooves OP (formation of the photosensitive permanent resist layer 12). However, it is a matter of course that the process sequence is not limited to this case, and various modifications can be considered.

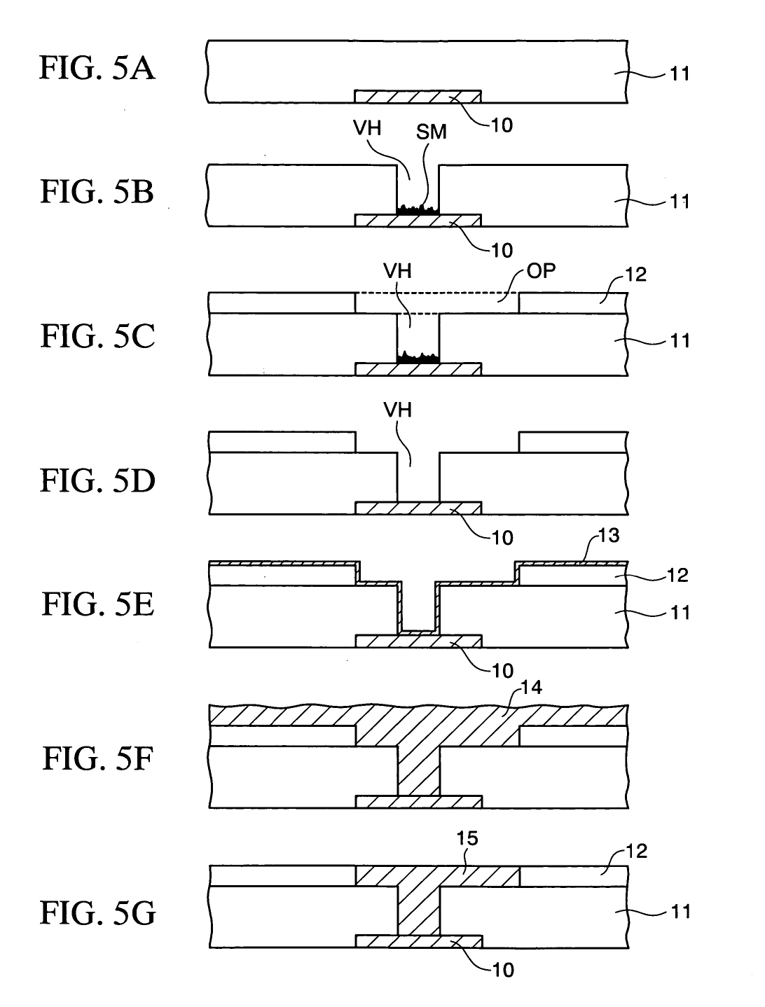

FIGS. 5A to 5G show a wiring formation process according to one modification. As shown in FIGS. 5B to 5D, the process is carried out by performing, in order, the formation of the via holes VH, the patterning of the wiring grooves OP, and desmearing. These processings are the same as those performed in the steps of FIGS. 1B, 1D, and 1C, respectively. Further, the processings performed in the steps of FIGS. 5A and 5E to 5G are also the same as those performed in the steps of FIGS. 1A and 1E to 1G, respectively. Accordingly, these processings will not be further described here.

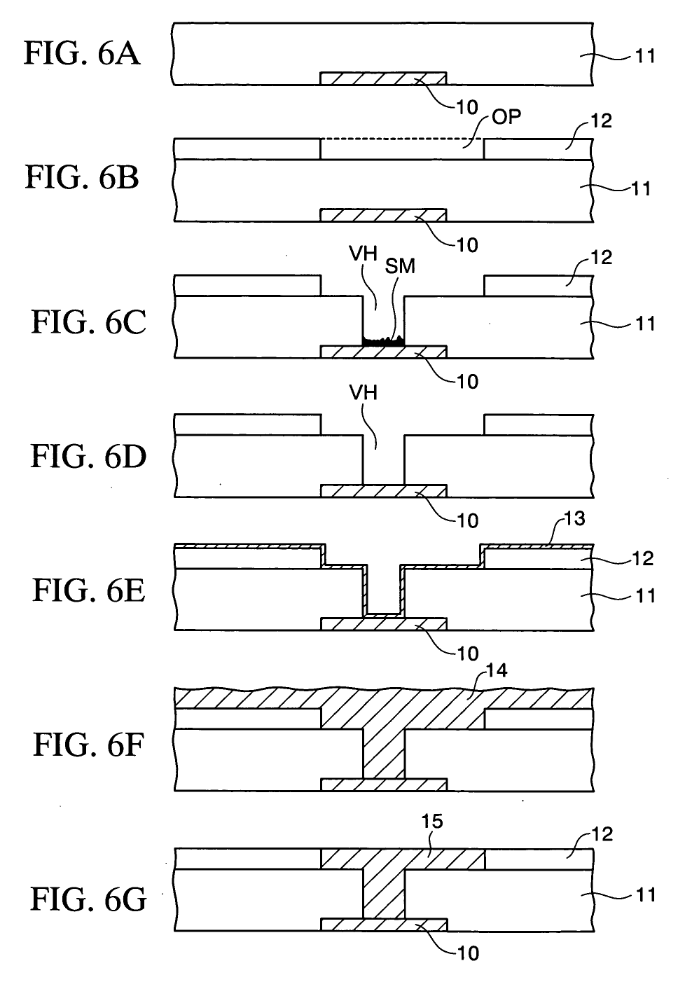

FIGS. 6A to 6G show a wiring formation process according to another modification. As shown in FIGS. 6B to 6D, the process is carried out by performing, in order, the patterning of the wiring grooves OP, the formation of the via holes VH, and desmearing. Similarly, these processings are the same as those performed in the steps of FIGS. 1D, 1B, and 1C, respectively. Further, the processings performed in the steps of FIGS. 6A and 6E to 6G are also the same as those performed in the steps of FIGS. 1A and 1E to 1G, respectively. Accordingly, these processings will not be further described here.

Also in the modifications shown in FIGS. 5A to 5G and FIGS. 6A to 6G, when necessary, the surfaces of the interlayer insulating layer 11 and the photosensitive permanent resist layer 12 may be roughened (formation of dips and bumps) by dry etching or the like after desmearing has been performed (before the seed layer 13 is formed).

Incidentally, in the modifications shown in FIGS. 5A to 5G and FIGS. 6A to 6G, in the case where desmear is performed by wet etching after the photosensitive permanent resist layer 12 has been formed, a specific material which meets a requirement of desmear resistance needs to be selected as the material constituting the permanent resist layer 12.

What is claimed is:

1. A method of fabricating a wiring board, including a wiring formation process using a damascene method, the wiring formation process comprising the steps of:
forming via holes reaching an underlying wiring layer, in an interlayer insulating layer formed on the underlying wiring layer;
removing smears caused when the via holes have been formed;
forming on the interlayer insulating layer a photosensitive permanent resist layer having opening portions according to a shape of a required wiring pattern located above the via holes; and
forming the required wiring pattern by filling conductive material into the via holes and the opening portions.

2. The method according to claim 1, further comprising, between the step of removing smears and the step of forming a photosensitive permanent resist layer, a step of roughening a surface of the interlayer insulating layer.

3. The method according to claim 1, further comprising, between the step of forming a photosensitive permanent resist layer and the step of forming the required wiring pattern, a step of roughening surfaces of the interlayer insulating layer and the photosensitive permanent resist layer.

4. A method of fabricating a wiring board, including a wiring formation process using a damascene method, the wiring formation process comprising the steps of:
forming via holes reaching an underlying wiring layer, in an interlayer insulating layer formed on the underlying wiring layer;
forming on the interlayer insulating layer a photosensitive permanent resist layer having opening portions according to a shape of a required wiring pattern located above the via holes;
removing smears caused when the via holes have been formed; and
forming the required wiring pattern by filling conductive material into the via holes and the opening portions.

5. A method of fabricating a wiring board, including a wiring formation process using a damascene method, the wiring formation process comprising the steps of:
forming, on an interlayer insulating layer formed on an underlying wiring layer, a photosensitive permanent resist layer having opening portions according to a shape of a required wiring pattern located above the underlying wiring layer;
forming via holes reaching the underlying wiring layer, in the interlayer insulating layer;
removing smears caused when the via holes have been formed; and
forming the required wiring pattern by filling conductive material into the via holes and the opening portions.

6. The method according to any one of claims 4 and 5, further comprising, between the step of removing smears and the step of forming the required wiring pattern, a step of roughening surfaces of the interlayer insulating layer and the photosensitive permanent resist layer.

7. The method according to any one of claims 1, 4, and 5, wherein in the step of removing smears, the smears are removed by wet etching using permanganate.

8. The method according to any one of claims 1, 4, and 5, wherein in the step of forming a photosensitive permanent resist layer, an insulating material having a linear expansion coefficient of 70 ppm/° C. or less and a tensile strength of 70 MPa or more is used as a material of the photosensitive permanent resist layer.

9. The method according to claim 1, wherein the step of forming the wiring pattern comprises the steps of:
forming a first conductor layer on an entire surface including inner walls of the via holes and the opening portions;
forming a second conductor layer on the first conductor layer by filling insides of the via holes and the opening portions; and
polishing and planarizing a surface of the second conductor layer until the photosensitive permanent resist layer is exposed.

10. The method according to claim 9, wherein the step of forming a second conductor layer comprises the steps of:
selectively filling the via holes by pulse plating; and
filling the opening portions by DC plating.

11. The method according to claim 9, wherein the step of polishing and planarizing a surface of the second conductor layer is performed by mechanical polishing.

12. The method according to claim 9, wherein the step of polishing and planarizing a surface of the second conductor layer is performed by a combination of mechanical polishing and chemical polishing by etching.

13. The method according to any one of claims 1, 4, and 5, further comprising, after repeating the wiring formation step until a required number of wiring layers are obtained, a step of forming a protective film on each of both surfaces so that pad portions delimited in required portions of outermost wiring patterns are exposed.

14. The method according to claim 4, wherein the step of forming the wiring pattern comprises the steps of:
forming a first conductor layer on an entire surface including inner walls of the via holes and the opening portions;
forming a second conductor layer on the first conductor layer by filling insides of the via holes and the opening portions; and
polishing and planarizing a surface of the second conductor layer until the photosensitive permanent resist layer is exposed.

15. The method according to claim 14, wherein the step of forming a second conductor layer comprises the steps of:
selectively filling the via holes by pulse plating; and
filling the opening portions by DC plating.

16. The method according to claim 5, wherein the step of forming the wiring pattern comprises the steps of:
forming a first conductor layer on an entire surface including inner walls of the via holes and the opening portions;
forming a second conductor layer on the first conductor layer by filling insides of the via holes and the opening portions; and
polishing and planarizing a surface of the second conductor layer until the photosensitive permanent resist layer is exposed.

17. The method according to claim 16, wherein the step of forming a second conductor layer comprises the steps of:
selectively filling the via holes by pulse plating; and
filling the opening portions by DC plating.
